(19) United States
(12) Patent Application Publication
(10) Pub. No.: US 2025/0118815 A1
(43) Pub. Date: Apr. 10, 2025

(54) SERIAL BATTERY CELL FORMATION DEVICE

(71) Applicant: GREEN POWER CO., LTD., Hwaseong-si Gyeonggi-do (KR)

(72) Inventors: Jung Goo CHO, Suwon-si (KR); Kyu Min CHO, Hwaseong-si (KR); Jin Sik PARK, Daejeon (KR)

(73) Assignee: GREEN POWER CO., LTD., Hwaseong-si Gyeonggi-do (KR)

(21) Appl. No.: 18/984,021

(22) Filed: Dec. 17, 2024

Related U.S. Application Data
(63) Continuation of application No. PCT/KR2023/015798, filed on Oct. 13, 2023.

(30) Foreign Application Priority Data
Oct. 15, 2022 (KR) 10-2022-0132805
Nov. 30, 2022 (KR) 10-2022-0165283

(51) Int. Cl. H01M 10/42; H01M 10/04; H01M 10/48; H01M 50/211; H01M 50/298; H01M 50/51; H01M 50/574

(52) U.S. Cl. CPC H01M 10/425; H01M 10/0404; H01M 10/482; H01M 50/211; H01M 50/298; H01M 50/51; H01M 50/574; H01M 2010/4278

(57) ABSTRACT

The present disclosure relates to a battery cell formation device, and more particularly, to a serial battery cell formation device that reduces the length and number of power cables in a device that performs charging and discharging by connecting a plurality of battery cells in series, thereby minimizing power cable loss and reducing cost.

### CROSS-REFERENCE TO RELATED APPLICATIONS

This application is a continuation of International Patent Application No. PCT/KR2023/015798, filed on Oct. 13, 2023, which claims the benefit of Korean Patent Application Nos. 10-2022-0165283, filed on Nov. 30, 2022, and 10-2022-0132805, filed on Oct. 15, 2022, in the Korean Intellectual Property Office, the disclosures of which incorporated herein in their entirety by reference.

### TECHNICAL FIELD

The present disclosure relates to a battery cell formation device that enters a formation process in a battery manufacturing line.

### BACKGROUND ART

A secondary battery has been variously used in a portable electronic apparatus, an electric vehicle, an energy storage apparatus, and the like. A demand for the secondary battery has rapidly increased in recent due to explosive growth of the electric vehicle, and is expected to further increase in the future in order to overcome problems such as depletion of resources and destruction of a global environment due to fossil fuels. In accordance with an increase in a capacity of a battery, a battery cell having a capacity of 100A or more are being mainly produced as a unit battery cell.

Describing manufacturing process of the secondary battery, the manufacturing process of the secondary battery mainly includes an electrode generation process, an assembly process, and a formation process. The formation process is a process that forms chemicals inside a secondary battery by charging and discharging the secondary battery, thereby making the secondary battery that can be substantially used. This formation process is the process that takes the most time. It usually takes about 5 to 6 hours to form one cell. Currently, a method of separately attaching respective battery cells of the secondary battery to a charging and discharging apparatus to form the respective battery cells is adopted, such that a great number of formation equipments should be used in order to increase the productivity of the secondary battery and a charging and discharging cable should be separately connected to each battery cell, which causes a problem that a large space is occupied and costs increase. In particular, a thick cable should be connected in order to form a large-capacity battery cell of 100A or more, and thus, a space problem and a much more serious problem are caused.

### DISCLOSURE

### Technical Problem

Generally, the battery formation device has a problem in that a long power cable should be used because the distance between the power supply unit and the battery cell is far, and the cable thickness increases due to the increase in the capacity of the battery cell, which increases the size of the equipment, increases costs, and causes a lot of loss.

The present disclosure has been made to solve the above problems, and an object of the present disclosure is to reduce the length and number of power cables when configuring a battery cell formation device that performs charging and discharging by connecting a plurality of battery cells in series, thereby minimizing the loss of the power cables.

### Technical Solution

To achieve the above object, in one general aspect, a serial battery cell formation device performing charging and discharging by connecting a plurality of battery cells in series includes: a unit charging and discharging module including one battery cell, a power supply unit that charges and discharges the one battery cell, a pair of (+) (−) power cables that connect the one battery cell and the power supply unit, a voltage sensor that senses a voltage of the battery cell, and a current sensor that senses s a current of the battery cell;
a channel controller controlling one or more unit charging and discharging modules; and
a master controller connected to a plurality of channel controllers through communication and transmitting various commands and monitoring a status,
in which the plurality of unit charging and discharging modules are configured to be vertically stacked so that the plurality of battery cells are connected in series, and
a (−) power cable of one unit charging and discharging module and a (+) power cables of adjacent unit charging and discharging modules are integrated to form one shared power cable.

In addition, according to the present disclosure, in the case of the pouch-type battery cell, when configuring the battery cell formation device, one or more trays in which a plurality of battery cells are accommodated may be included, and a direction of the electrode of the cell may be alternately arranged in the same tray so that the plurality of battery cells are connected serially by connecting a (−) polarity of one cell to a (+) polarity of adjacent cells.

Further, according to the present disclosure, in the case of the pouch-type battery cell, when configuring the battery cell formation device, two trays may be stacked vertically, the two trays are composed of a first tray in which (+) electrodes are arranged in one direction and a second tray in which (+) electrodes are arranged in an opposite direction to the first tray, and the battery cell of the first tray and the battery cell of the second tray may be alternately connected in series.

### Advantageous Effects

In the case of the serial battery cell formation device according to the present disclosure, when configuring the battery cell formation device that performs charging and discharging by connecting the plurality of battery cells in series, by reducing the number of power cables and simplifying the structure of the harness cable for connecting the plurality of pouch-type battery cells in series, it is possible to dramatically shorten the cable length, thereby minimizing the loss caused by the cable and the cost for the cable connection. Accordingly, the serial battery cell formation device according to the present disclosure has the advantages of minimizing the cost, minimizing the size, and performing the formation process very efficiently.

### BRIEF DESCRIPTION OF THE DRAWINGS

FIG. 1 is a conceptual diagram of a battery formation device.

FIG. 2 is a diagram for describing a battery cell formation device according to a conventional individual charging and discharging method.

FIG. 3 is a graph of charging and discharging voltage and current characteristics of a general battery cell.

FIG. 4 is an actual appearance of a conventional battery cell formation device.

FIG. 5 is a configuration diagram of a conventional battery cell formation device.

FIG. 6 is a configuration diagram of a serial battery cell formation device according to the present disclosure.

FIG. 7 and FIG. 8 are configuration diagrams of a serial battery cell formation device according to the present disclosure when a non-isolated sensor is used.

FIG. 9 is a configuration diagram of a power supply unit of the serial battery cell formation device according to the present disclosure.

FIG. 10 is a graph of voltage and current characteristics of the serial battery cell formation device according to the present disclosure.

FIG. 11 is a diagram illustrating a battery cell serial connection method according to an upper and lower tray arrangement having the same polarity.

FIG. 12 is a diagram illustrating a battery cell serial connection method according to an upper and lower tray arrangement having opposite polarity according to the present disclosure.

### BEST MODE

A preferred embodiment of the present disclosure will be described in detail with reference to the accompanying drawings. The following detailed description is merely an example, and merely illustrates exemplary embodiments of the present disclosure.

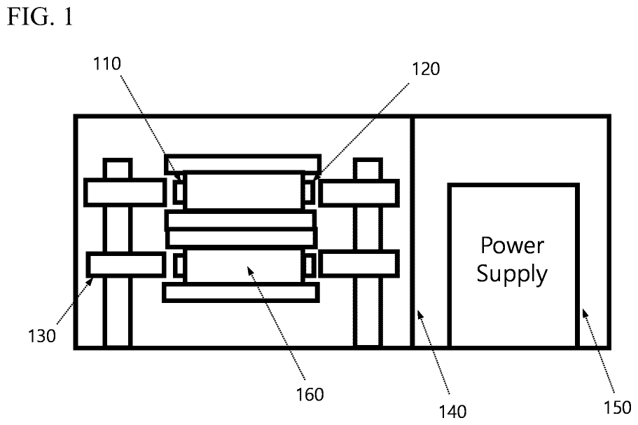

FIG. 1 is a general conceptual diagram of a battery formation device.

A battery that has been physically assembled is formed by forming internal chemicals using a battery formation device to actually exhibit battery characteristics. When the assembly of the battery cell is completed, the formation process goes through a pre-charging process of removing (de-gassing) gas generated from a cell while initially charging a battery cell to a SOC level of about 30% at a constant current, and a main charging process of charging the battery cell to the SOC of 100% and then discharging the battery cell again.

In this regard, the battery formation device may be configured to include a battery cell formation device that has a power supply device 150 that rectifies and transforms commercial AC power and performs a function of charging a target battery with current supplied from the power supply device 150.

The battery cell formation device includes at least one tray 160 for accommodating a battery cell to be charged within the device, and the tray 160 is formed in a plate shape having a thickness and has an accommodating space for accommodating at least one battery cell therein.

The battery cell formation device may include a plurality of unit charging and discharging units that perform an operation of charging and discharging a plurality of batteries by electrically connecting electrodes 110 and 120 of the plurality of battery cells mounted on the tray 160, and the unit charging and discharging units may be arranged to correspond to one battery cell one-to-one, and may be configured to include a plurality of charging and discharging grippers 130 for pressing probes or leads for connecting to the electrodes of the corresponding battery cells.

A jig unit including the tray 160 and a jig and a power supply unit including the power supply device 150 are generally separated by a compartment 140, so heat generated from the power device 150 does not affect the battery cells. In addition, in order to charge the battery cells, a power cable connecting the battery cells and the power supply 150 is required.

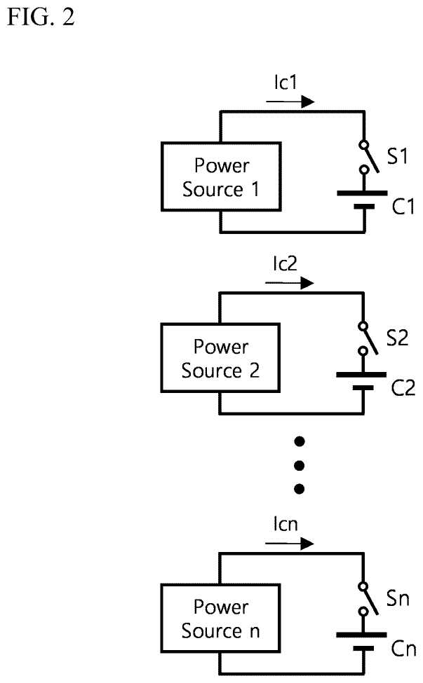

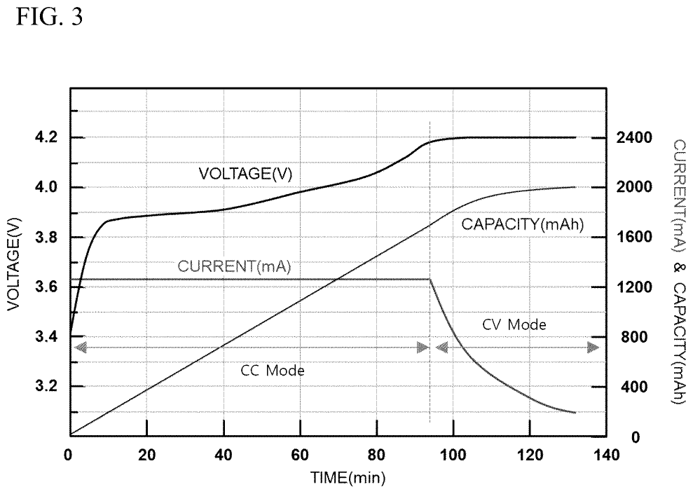

FIG. 2 is a diagram for describing a battery cell formation device according to a conventional individual charging and discharging method, and FIG. 3 is an example diagram of a graph of charging and discharging voltage and current characteristics of the battery cell by the battery cell formation device. In general, the battery cell formation device is a device that performs charging and discharging to ensure that the battery cell produced in a battery production line has proper characteristics.

Referring to FIG. 3, the battery cell formation device charges the battery cells by connecting the power supply to the battery cells, and includes a constant current charging mode that charges at a constant current and a constant voltage charging mode that applies a constant voltage. The battery cell formation device operates to supply a constant current to the battery at the beginning of the battery cell charging, and when the battery cell voltage reaches an end voltage, the constant voltage charging mode operates so the battery cell is fully charged.

Referring to FIG. 2, in the case of the battery cell formation device according to the conventional individual charging and discharging method, a separate power supply is provided for each battery cell to perform charging and discharging, thereby enabling individual constant current control and constant voltage control for each battery cell.

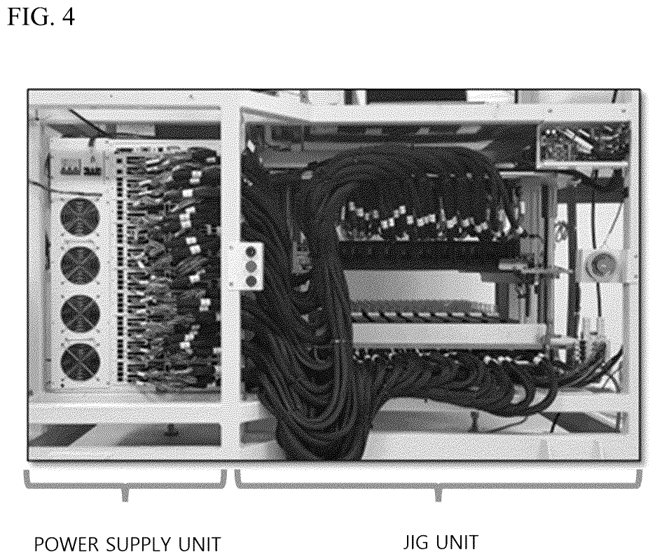

FIG. 4 illustrates the actual appearance of the battery cell formation device according to the conventional individual charging and discharging method. Referring to FIG. 4, it can be seen that the cable connected from the power supply unit on the left to the electrode of the jig unit takes up a lot of space. That is, in the case of the conventional battery cell formation device, in order to configure the device that simultaneously charges/discharges the plurality of battery cells, there is a problem of increasing installation cost and taking up a lot of space due to the power supply unit, the connection cables provided for each battery cell, etc. This problem is becoming more serious as the capacity of battery cells increases.

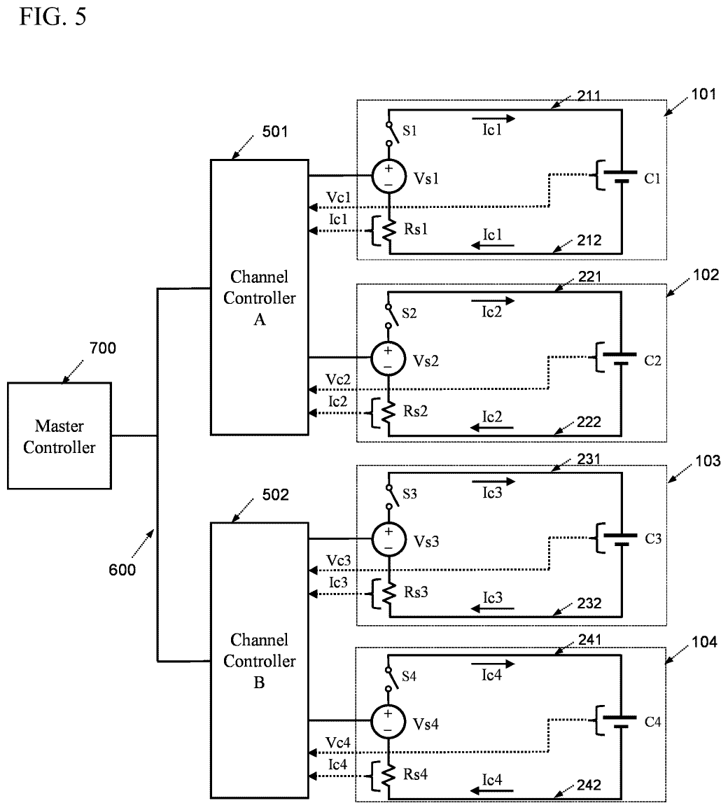

FIG. 5 illustrates a more detailed configuration diagram of the conventional battery cell formation device. Referring to FIG. 5, the battery cell formation device is basically composed of a unit charging and discharging module (e.g., based on a first unit charging and discharging module 101) that includes one battery cell C1, a power supply unit Vs1 for charging and discharging one battery cell, (+) (−) power cables 211 and 212 for connecting one battery cell C1 and the power supply unit Vs1, a relay S1 provided between the power supply Vs1 and the battery cell C1, a voltage sensor Vc1 for sensing the voltage of the battery cell C1, and a current sensor Rs1 for sensing the current, and when configured to charging and discharging the plurality of battery cells simultaneously, the plurality of unit charging and discharging modules 101, 102, 103, and 104 as described above may be provided according to the number of battery cells.

Meanwhile, in the following, since four battery cells to be charged and discharged are provided, it is described as an example that four unit charging and discharging modules are implemented, but it is not necessarily limited thereto.

Here, channel controllers 501 and 502 controlling one or more unit charging and discharging modules may be included, and when the plurality of unit charging and discharging modules are provided, a master controller 700 that issues various commands to the plurality of channel controllers and monitors various states may be included. Meanwhile, in FIG. 5, it is exemplified that control is performed through one channel controller for two unit charging and discharging modules, but it is not necessarily limited thereto.

Meanwhile, in the conventional battery cell formation device, the unit charging and discharging module (ex: based on the first unit charging and discharging module 101) is configured in a form in which the (+) (−) power cables 211 and 212 are individually connected from each electrode of the battery cell to the corresponding electrode of the power supply unit Vs1, and thus, in order to configure the device that simultaneously charges/discharges the plurality of battery cells, the corresponding (+) (−) power cables should be provided for each battery cell, which causes problems of increasing the installation cost increases and taking up a lot of space. For example, since the distance between the power supply unit and the battery cell is far, a long power cable should be connected, and as the capacity of the battery cell increases, the thickness of the power cable increases, which increases the size of the device, increases the costs, and causes a lot of loss.

In order to overcome the limitations of the conventional battery cell formation device as described above, the present disclosure proposes a new type of connection structure of the battery cell formation device that greatly simplifies the structure of the cable for simultaneously charging and discharging the plurality of battery cells compared to the conventional one. For example, not only does the number of power cables required for simultaneously charging and discharging the plurality of battery cells decrease by almost half compared to the conventional one, but also the actual current of the power cables is made almost zero, thereby drastically reducing the loss of the power cables, thereby enabling the charging and discharging process of each battery cell to be performed more efficiently.

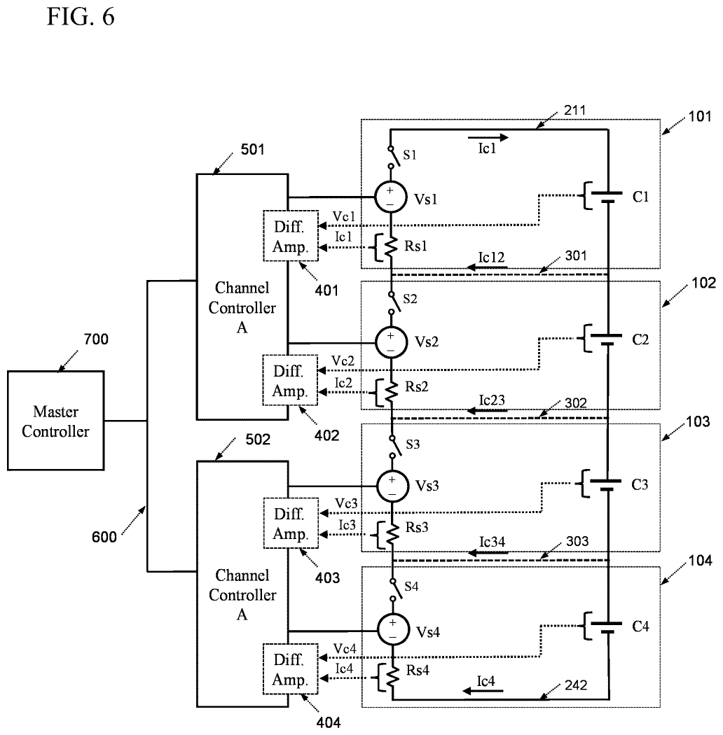

FIG. 6 is a configuration diagram of the serial battery cell formation device according to the present disclosure.

The serial battery cell formation device according to the present disclosure vertically stacks the plurality of unit charging and discharging modules so that the plurality of battery cells are connected in series. FIG. 6 illustrates an example of stacking four of the unit charging and discharging modules. Here, the vertical stacking does not mean being limited to physical vertical stacking, but means that the (+) (−) electrodes of adjacent battery cells are electrically stacked by connecting each other. In addition, the channel controllers 501 and 502 controlling one or more unit charging and discharging modules may be included, and when the plurality of channel controllers are provided, the master controller 700 that issues various commands to the plurality of channel controllers and monitors various states may be included. The plurality of channel controllers and the master controller 700 may be connected via a communication line 600.

The channel controllers 501 and 502 independently control the output voltage and current of each unit charging and discharging module, thereby independently controlling the charging and discharging current and voltage of each cell connected in series.

In the present disclosure, the channel controllers 501 and 502 initially control the output current of all the unit charging and discharging modules to be constant, so all the cells connected in series are charged with constant current, and when the voltage of some of the cells reaches the end voltage, controls to switch the cells to be charged with a constant voltage to maintain a constant voltage, and the remaining cells to be continuously charged with a constant current. Thereafter, among the remaining cells, those that reach the end voltage are switched to constant voltage charging in the order in which they reach the end voltage, and among the cells undergoing constant voltage charging, those whose charge current falls below a certain value are terminated for charging, so that all cells are sequentially terminated for charging.

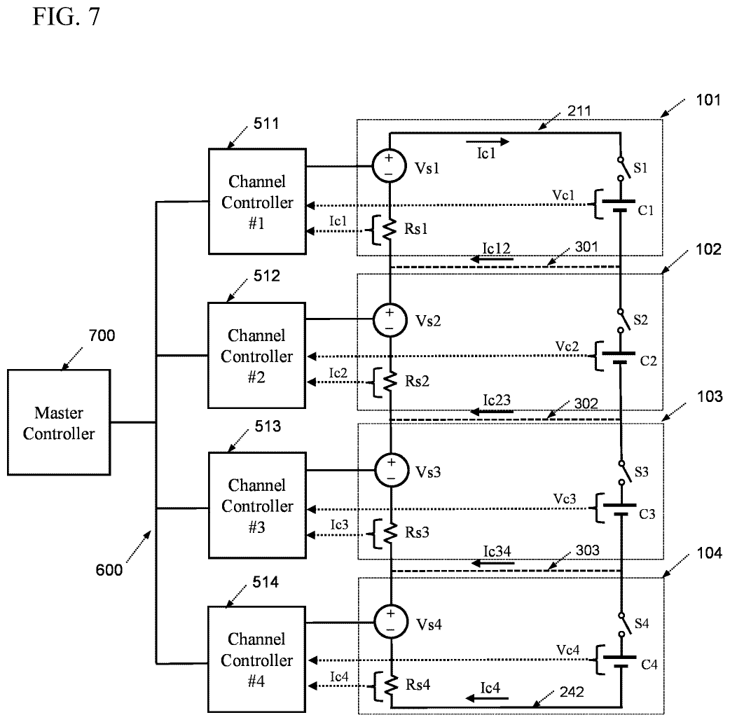

In the present disclosure, the power supply unit included in one or more unit charging and discharging modules may have a circuit breaker capable of cutting off the output of the power supply unit and current sensors Rs1 to Rs4 capable of measuring the output current configured in series to the output of the power supply unit. For example, output cutoff switches S1 to S4 for charging and discharging one battery cell and cutting off the output may be included in the output terminal of the power supply unit, which has the effect of simplifying the configuration compared to the case where the switches are provided around the battery cells as in the configuration of FIG. 7, since the output cutoff switches S1 to S4 are implemented on the channel board including the power supply unit. Meanwhile, in another embodiment, the output cutoff switches may be arranged around the battery cells as in FIG. 7. In addition, FIG. 7 illustrates a case where the unit charging and discharging modules 101 to 104 are implemented to use channel controllers 511 to 514 in which separate ground lines are separated for each channel.

In the case of the present disclosure, when one of the plurality of battery cells is defective, the output cutoff switches S1 to S4 of the corresponding power supply unit is turned off to isolate the corresponding cell. In this case, the shared power cable adjacent to the corresponding cell does not have its current offset, so the rated current flows.

Here, the output cutoff switch S1 to S4 may be implemented as a semiconductor switch element, but may preferably be implemented using the relays S1 to S4 to minimize the turn-on resistance loss.

Meanwhile, the serial battery cell formation device according to the present disclosure has a difference from the conventional method in the method of connecting the battery cells and the power cable in order to further simplify the structure of the cable for charging and discharging the plurality of battery cells compared to the conventional method.

For example, referring to FIG. 6, the serial battery cell formation device according to the present disclosure is configured by vertically stacking the plurality of unit charging and discharging modules, but the (−) power cable of one overlapping unit charging and discharging module and the (+) power cable of the adjacent unit charging and discharging module may be integrated to form one shared power cable 301.

In this case, by replacing two power cables that overlap between adjacent unit charging and discharging modules with one shared power cable, the number of power cables may be reduced by almost half compared to the structure of the conventional battery cell formation device. For example, when the number of power cables for configuring the battery cell formation device in the conventional case requires two power cables per battery cell, in the case of the configuration of the battery cell formation device according to the present disclosure, the number of battery cells connected in series, only +1 power cable is required.

In addition, since the charging and discharging currents in the shared power cable are mutually offset and almost no current flows, the cable loss may be drastically reduced. In particular, in the constant current charging mode where the current of each unit charging and discharging module is the same, the current flowing on the shared power cable is completely zero, so the loss of the shared power cable is zero. In the constant voltage charging mode, a small amount of current may flow due to the capacity difference between the battery cells, but current is much lower than the conventional method.

In the present disclosure, the number of vertically stacked unit charging and discharging modules may be limited to a preset range that does not cause electric shock to a human body when human access to the formation device is permitted. Preferably, the preset range may be limited to a voltage reference of 50 to 60 V of the stacked battery cell. When the human access is restricted while the power supply unit is turned on, the number of stacked unit charging and discharging modules may be increased without limitation. Assuming 72 channel formation devices, which is generally used in the battery cell for EV, the total voltage of the stacked battery cells becomes 72×4.2 V=288.2 V. In this case, an isolation voltage of the power supply unit, the power cable, a power contactor connecting the power cable and the electrodes of the battery cells, the tray containing the battery cells, etc., is required to be high in proportion to the number of stacked unit charging and discharging modules. The power supply unit, the power cable, and the battery cell should have an increased isolation strength relative to the chassis, the jig, the cell tray, the housing, etc., which they come into contact with, in proportion to the number of battery cells that are stacked.

In addition, it is preferable that the power supply unit have a function that prevents accidents such as electric shock when a person performs inspection of the battery cell formation device by turning off all power supply units when the door of the battery cell formation device is opened.

On the other hand, in the case of the battery cell formation device such as the present disclosure, since each battery cell is stacked vertically and connected in a form that shares the power cables between neighboring unit charging and discharging modules, there is a problem that communication confusion may occur between each unit charging and discharging module. Accordingly, in the case of the present disclosure, it is preferable that a communication driver (not illustrated) included in the channel controllers 501 and 502 of the unit charging and discharging module and the master controller 700 is implemented as an isolated driver that may overcome the potential difference for communication between one master controller and the plurality of channel controllers.

As illustrated in FIG. 6, when the channel controller controls two or more unit charging and discharging modules, the voltage sensor and the current sensor included in the unit charging and discharging modules have different potential levels, so they may not be sensed using a non-isolated sensor, and should use an isolated sensor or remove a DC component of each sensor using differential amplifiers 401, 402, 403, and 404. In addition, the power supply unit and the channel controller may remove the DC component by grounding them through a capacitor instead of directly grounding them to the ground.

Meanwhile, the serial battery cell formation device according to the present disclosure can also be configured using the non-isolated sensors as the voltage sensor and the current sensor.

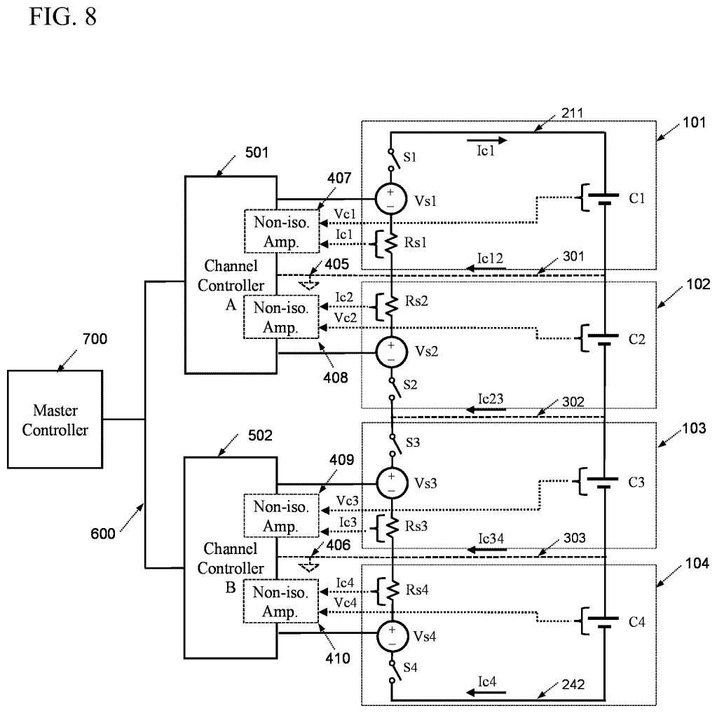

FIG. 8 is a configuration diagram of the battery cell formation device according to the present disclosure using the non-isolated sensor.

Referring to FIG. 8, the serial battery cell formation device according to the present disclosure may be configured such that two adjacent unit charging and discharging modules are grouped into two units, and the current sensors, the power supply units, and the output cutoff switches of each unit charging and discharging module are symmetrically connected in series to the shared power cable therebetween as the center.

In this way, when the current sensors, the power supply units, and the output cutoff switches of two adjacent unit charging and discharging modules are arranged symmetrically with the shared power cable as the standard, the voltage and current of two adjacent cells may be measured using the non-isolated sensor. In this case, non-isolated amplifiers 407, 408, 409, and 410 may be used.

More specifically, two adjacent unit charging and discharging modules are controlled by one channel controller, but the power ground and the ground of the channel controller are shared with the shared power cable 405 and 406, so the voltage and current of two adjacent cells may be measured using the non-isolated voltage sensor and the non-isolated current sensor.

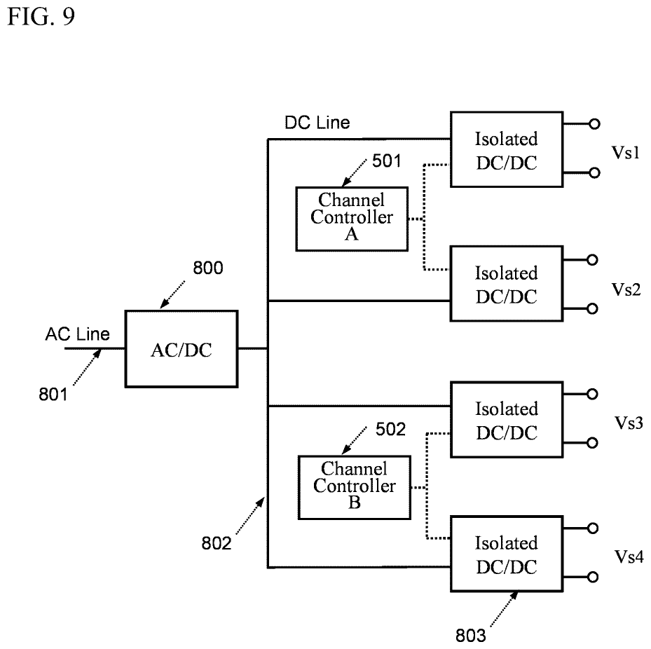

FIG. 9 is a configuration of the power supply unit of the serial battery cell formation device according to the present disclosure.

Referring to FIG. 9, the power supply unit of each channel is composed of an isolated DC/DC converter 803. The isolated DC/DC converter 803 is controlled by the channel controllers 501 and 502 and transmits data such as voltage, current, and temperature of the battery cell to the corresponding channel controller. The input of the isolated DC/DC converter receives DC power supplied by an AC/DC converter 800. The plurality of isolated DC/DC converters may be connected to a DC power line 802 connected to one AC/DC converter. The input of the AC/DC converter may be connected to a utility AC power line 801.

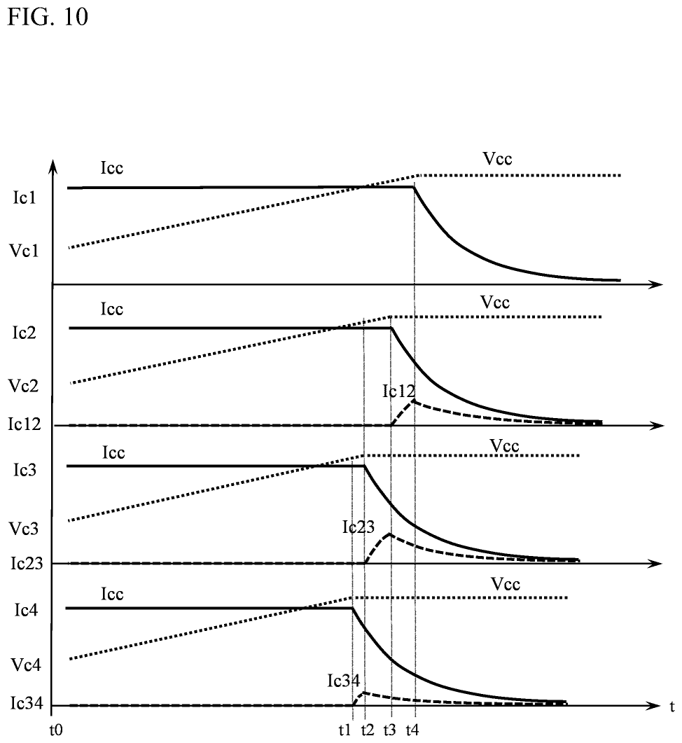

FIG. 10 is a graph of voltage and current characteristics of the serial battery cell formation device according to the present disclosure.

Referring to FIG. 10, in the present disclosure, when all battery cells are operating normally, the currents flowing in the shared power cables 301, 302, and 303 offset each other and become zero in the section where they are charged with a constant current, and when they are charged with a constant voltage in the constant current charging section, a current flows corresponding to the current imbalance due to the difference in capacity between two adjacent battery cells. However, since the current is very small compared to the current flowing in the battery cells, there is an effect of dramatically reducing the loss caused by the power cables. It is preferable to implement all unit charging and discharging modules to start constant current charging at the same time so that the current of the shared power cables is canceled out as much as possible. Since the current flowing through the shared power cable is very small compared to the rated charging and discharging current, the thickness of the shared power cable may be significantly reduced. However, when the defective battery cell occurs, the relays S1 to S4 connected in series to the defective battery cell are turned off, and the rated current flows in the shared power cable connected to the (+) terminal of the defective battery cell and the shared power cable connected to the (−) terminal thereof. Therefore, the capacity of the shared power cable may not be reduced and should be used at its rated capacity. In addition, the relays S1 to S4 may be arranged adjacent to the power supply unit Vs1 to Vs4 side as illustrated in FIGS. 6 and 8, but may also be arranged adjacent to the battery cell side as illustrated in FIG. 7.

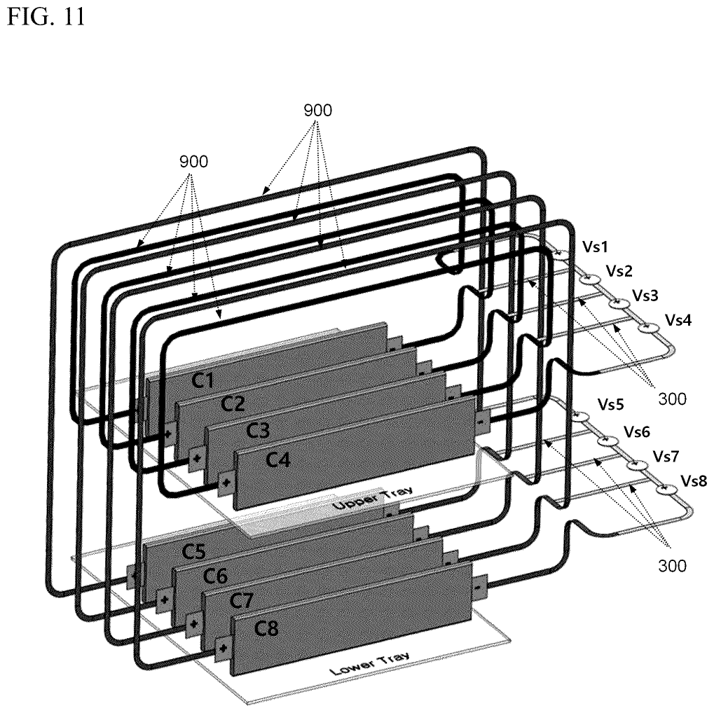

FIG. 11 is a diagram illustrating a battery cell serial connection method in a general upper and lower tray arrangement having the same electrode direction.

As illustrated in FIG. 11, the cell serial connection method is a method in which the cells of the upper tray are serially connected to the cells of the upper tray, and the cells of the lower tray are serially connected to the cells of the lower tray. In this case, in order to connect the cells in series, a serial connection cable 900 for connecting the (+) electrode of one cell to the (−) electrode of the next cell should be connected in the opposite direction from one side of the cell, so the length of the serial connection cable 900 has to be long. In addition, since the current does not offset and the battery cell current always flows in the serial connection cable 900, there is no difference from the existing individual charging and discharging method in terms of cable length and cable loss. A length of a shared power cable 300 is configured to be short, but since the current does not flow normally, it does not help much.

On the other hand, in the case of the battery cell serial connection method according to the present disclosure, the length of the serial connection cable for connecting the plurality of battery cells in series may be drastically reduced by alternating the electrode directions of the battery cells connected in series to each other.

A first method of alternating the electrode directions is a method of alternating the electrodes of the cells in the same tray (not illustrated). More specifically, the directions of the electrodes of the cells in the same tray are arranged alternately to connect a (−) polarity of one cell and a (+) polarity of the adjacent cell, thereby connecting the plurality of battery cells in series, and the shared power cable is pulled to the opposite side from the point of the serial connection so that two power supply units are connected around the shared power cable. In this case, the length of the serial connection cable may be configured to be the shortest, but there is a disadvantage that there is a high possibility of errors in the electrode directions during the production process of the battery cells.

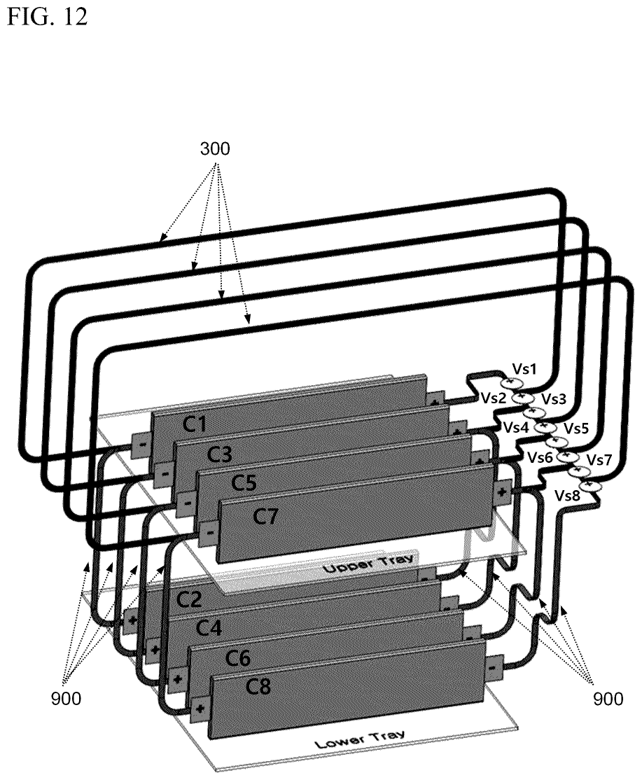

The second method is a method of alternately connecting serially the cells of the upper tray and the cells of the lower tray, where the electrode directions are arranged differently, as illustrated in FIG. 12. This method is relatively longer than the alternating electrode method within the same tray, but can drastically reduce the length of the serial connection cable compared to the general method.

More specifically, referring to FIG. 12, in the case of the present disclosure, when the battery cells C1 to C8 are pouch-type cells with (+) (−) electrodes at both ends of the cell, the trays are arranged in a structure in which two trays are stacked vertically, and the two trays may include a first tray (upper tray) in which the (+) electrodes of the cells are arranged in one direction, and a second tray (lower tray) below which the (+) electrodes of the cells are arranged in the opposite direction to the first tray.

Here, the (−) electrode of the first cell C1 of the first tray is connected to the electrode of the first cell C2 of the second tray, the (−) electrode of the first cell C2 of the second tray is connected to the (+) electrode of the second cell C3 of the first tray, and the (−) electrode of the second cell C3 of the first tray is again connected to the (+) electrode of the second cell C4 of the second tray, so the cells of the first tray and the second tray are alternately connected in series. The serial connection cable 900 connecting the cells of the first tray and the cells of the second tray has the advantage of having very little loss and a great cost-saving effect because the cell current always flows through all of the cells, but its length is very short.

The shared power cable of the unit charge and discharge module is connected from one side of the jig to the opposite side, so the cable length is configured to be long, but the number of cables is reduced by half, which helps reduce costs, and has the advantage of not contributing to heat generation because almost no current flows normally.

The configuration of the shared power cable is as follows.

A (+) electrode of a first cell C1 of the first tray is connected to an (+) output of a first power supply unit Vs1 through the power cable, and a (−) electrode of the first cell C1 of the first tray is connected to an output of the second power supply unit Vs2 through the shared power cable 300.

A (+) electrode of a second cell C2 of the first tray is connected to an output of the third power supply unit Vs3 through the shared power cable 300, and a (−) electrode of the second cell C2 of the first tray is connected to a (+) output of the fourth power supply unit Vs4 through the shared power cable 300.

A (+) electrode of a third cell C3 of the first tray is connected to an output of a fifth power supply unit Vs5 through the shared power cable 300, and the (−) electrode of the third cell C3 of the first tray is connected to an output of a sixth power supply unit Vs6 through the shared power cable 300.

A (+) electrode of a fourth cell C4 of the first tray is connected to an output of a seventh power supply unit Vs7 through the shared power cable 300, and a (−) electrode of the fourth cell (C4) of the first tray is connected to an output of an eighth power supply unit Vs8 through the shared power cable 300.

Similarly, a (+) electrode of an nth cell of the first tray is connected to a (+) output of a (2n-1) power supply unit through the shared power cable 300, and a (−) electrode of an nth cell of the first tray is connected to a (+) output of a (2n) power supply unit through the shared power cable 300.

The (−) electrode of the nth cell of the second tray is connected to a (−) output of the (2n) power supply unit through the power cable, and all of the (2n) power supply units in the first power supply unit are connected in series. Although exemplary embodiments of the present disclosure have been disclosed hereinabove with reference to the present specification and the drawings and specific terms have been used, they are merely used in a general sense in order to easily describe technical contents of the present disclosure and assist in the understanding of the present disclosure, and are not intended to limit the scope of the present disclosure. It will be apparent to those of ordinary skill in the art that other modifications based on the technical idea of the present disclosure are possible, in addition to exemplary embodiments disclosed herein.

### DESCRIPTION OF REFERENCE SIGNS

C1, C2, C3, C4, C5, C6, C7, C8: Battery cell
Vs1, Vs2, Vs3, Vs4: Power supply unit
S1, S2, S3, S4: Output cutoff switch, relay
Vc1, Vc2, Vc3, Vc4: Voltage sensor
Rs1, Rs2, Rs3, Rs4: Current sensor
101, 102, 103, 104: Unit charging and discharging module
211, 221, 231, 241: (+) power cable
212, 222, 232, 242: (−) power cable
300, 301, 302, 303: Shared power cable
401, 402, 403, 404: Differential amplifier
407, 408, 409, 410: Non-isolated amplifier
501, 502, 511, 512, 513, 514: Channel controller
600: Communication cable
700: Master controller
800: AC/DC converter
801: AC power line
802: DC power line
803: Isolated DC/DC converter
900: Serial connection cable

1. A serial battery cell formation device performing charging and discharging by connecting a plurality of battery cells in series, comprising:
a unit charging and discharging module including one battery cell,
a power supply unit that charges and discharges the one battery cell,
a pair of (+) (−) power cables that connect the one battery cell and the power supply unit,
a voltage sensor that senses a voltage of the battery cell, and
a current sensor that senses a current of the battery cell;
a channel controller controlling one or more unit charging and discharging modules; and
a master controller connected to a plurality of channel controllers through communication and transmitting various commands and monitoring a status,
wherein the plurality of unit charging and discharging modules are configured to be vertically stacked so that the plurality of battery cells are connected in series,
a (−) power cable of one unit charging and discharging module and a (+) power cables of adjacent unit charging and discharging modules are integrated to form one shared power cable.

2. The serial battery cell formation device of claim 1, wherein when a current of each unit charging and discharging module is the same, the current flowing in the shared power cable becomes zero.

3. The serial battery cell formation device of claim 1, wherein the channel controller independently controls an output voltage and current of each unit charging and discharging module to independently control charging and discharging current and voltage of each cell connected in series.

4. The serial battery cell formation device of claim 3, wherein the channel controller initially controls an output current of all unit charging and discharging modules to be constant so that all cells connected in series are charged at a constant current,
when a voltage of some of the cells reaches an end voltage, the corresponding cell is switched to be charged with a constant voltage to maintain a constant voltage, and the remaining cells continue to be charged with a constant current,
among the remaining cells, it switches to change the constant voltage in an order in which they reach the end voltage, and
among the cells being charged at the constant voltage, a cell whose charge current falls below a certain value terminates charging to sequentially terminate the charging of all cells.

5. The serial battery cell formation device of claim 1, wherein the power supply unit configures an output cutoff switch cutting off an output of the power supply unit and the current sensor measuring an output current in series to the output of the power supply unit.

6. The serial battery cell formation device of claim 1, wherein the unit charging and discharging modules are grouped into two units, and the current sensor, the power supply unit, and an output cutoff switch of each unit charging and discharging modules are configured to be symmetrically connected in series to the shared power cable therebetween as a center.

7. The serial battery cell formation device of claim 1, wherein the channel controller controls two adjacent unit charging and discharging modules with one channel controller, connects a ground of the channel controller to the shared power cable, and measures a voltage and current of the two adjacent cells using a non-isolated voltage sensor and a non-isolated current sensor.

8. The serial battery cell formation device of claim 1, wherein the master controller and the channel controller use an isolated communication driver that overcomes a potential difference for communication between one master controller and a plurality of channel controllers.

9. The serial battery cell formation device of claim 1, wherein when one of the plurality of battery cells is defective during the charging or discharging, an output cutoff switch of the corresponding power supply unit is turned off to separate the corresponding cell, and
when the corresponding cell is separated, the shared power cable adjacent to the corresponding cell does not cancel a current out so that a rated current flows.

10. The serial battery cell formation device of claim 1, wherein the shared power cable uses a capacity that allows a rated charging and discharging current to flow.

11. The serial battery cell formation device of claim 1, wherein when the battery cell has (+) (−) electrodes at both ends of the cell in a pouch type, the battery cell includes one or more trays in which the plurality of battery cells are accommodated, and a direction of the electrode of the cell is alternately arranged in the same tray so that the plurality of battery cells are connected serially by connecting a (−) polarity of one cell to a (+) polarity of adjacent cells, and the shared power cable is pulled to an opposite side from a serially connected point, so that two power supply units are connected to the shared power cable as a center.

12. The serial battery cell formation device of claim 1, wherein when the battery cell has (+) (−) electrodes at both ends of the cell in a pouch type,
two trays in which the plurality of battery cells are accommodated are arranged in a structure in which they are stacked vertically,
the two trays are arranged as a first tray in which the (+) electrode of the cell is arranged in one direction and a second tray in which the (+) electrode of the cell is arranged in an opposite direction to the first tray,
a (−) electrode of a first cell of the first tray is connected to a (+) electrode of a first cell of the second tray,
a (−) electrode of the first cell of the second tray is connected to a (+) electrode of a second cell of the first tray, and
a (−) electrode of the second cell of the first tray is again connected to a (+) electrode of a second cell of the second tray so that the cells of the first tray and the second tray are alternately connected in series.

13. The serial battery cell formation device of claim 12, wherein a (+) electrode of the first cell of the first tray is connected to a (+) output of the power supply unit through the power cable,
the (−) electrode of the first cell of the first tray is connected to a (+) output of a second power supply unit through the shared power cable,
the (+) electrode of the second cell of the first tray is connected to a (+) output of a third power supply unit through the shared power cable,
the (−) electrode of the second cell of the first tray is connected to a (+) output of a fourth power supply unit through the shared power cable,
a (+) electrode of a third cell of the first tray is connected to a (+) output of a fifth power supply unit through the shared power cable,
a (−) electrode of the third cell of the first tray is connected to a (+) output of a sixth power supply unit through the shared power cable,
a (+) electrode of a fourth cell of the first tray is connected to a (+) output of a seventh power supply unit through the shared power cable,
a (−) electrode of the fourth cell of the first tray is connected to a (+) output of an eighth power supply unit through the shared power cable,
a (+) electrode of an n-th cell of the first tray is connected to an (+) output of a (2n-1) power supply unit through the shared power cable,
a (−) electrode of the n-th cell of the first tray is connected to a (+) output of a (2n) power supply unit through the shared power cable,
a (−) electrode of an nth cell of the second tray is connected to a (−) output of the (2n) power supply unit through the power cable, and
all of the (2n) power supply units in the first power supply unit are connected in series.
